(19) United States
(12) Patent Application Publication
(10) Pub. No.: US 2022/0344936 A1
(43) Pub. Date: Oct. 27, 2022

(54) ESTIMATION OF DISTRIBUTION NETWORK RECOVERY AFTER DISASTER

(71) Applicant: One Concern, Inc., Menlo Park, CA (US)

(72) Inventors: Ahmad Wani, Mountain View, CA (US); Nicole Hu, Mountain View, CA (US); Chengwei Zhai, Menlo Park, CA (US); Jaskanwal Chhabra, Menlo Park, CA (US); Shabaz Patel, Menlo Park, CA (US); Youngsuk Kim, Menlo Park, CA (US)

(21) Appl. No.: 17/239,928

(22) Filed: Apr. 26, 2021

(51) Int. Cl. H02J 3/00; G06Q 50/06

(52) U.S. Cl. CPC H02J 3/0012; H02J 3/002; G06Q 50/06; H02J 2203/20

(57) ABSTRACT

Methods, systems, and computer programs are presented for estimating recovery of a distribution network after a disaster. One method includes an operation for generating a synthetic distribution network based on locations of substations in a geographical area. Further, the method includes operations for estimating damages to the synthetic distribution network based on disaster data, and for performing a simulation to estimate how the synthetic distribution network is repaired. The output of the simulation includes information on a lifeline recovery timeline for each building in the geographical area. Further, the method includes presenting, in a user interface, the recovery timeline for one or more buildings.

### TECHNICAL FIELD

The subject matter disclosed herein generally relates to methods, systems, and machine-readable storage media for estimating the recovery of a distribution network after a disaster.

### BACKGROUND

Natural disasters, such as earthquakes, high winds, hurricanes, floods, etc., create disruptions to the business operations businesses in the area impacted by the disaster. Businesses want to plan for the impact of disasters, which includes understanding the estimated downtime (e.g., lack of power) caused by the disasters.

The problem of estimating downtime in one facility is complicated because the estimation needs to account, not only for the restore of power to the building, but also from other related factors, such as downtime in other facilities that provide support (e.g., raw materials), availability of workers to return to work, etc. For example, if the power returns to the facility, but the workers can not get to work because public transportation is unavailable or roads are blocked, then the business will not be able to operate.

Further compounding the problem is that businesses do not have visibility to the structure of the power grid, so trying to model the recovery of the power-distribution network without knowing the actual structure of the network is challenging.

### BRIEF DESCRIPTION OF THE DRAWINGS

Various of the appended drawings merely illustrate example embodiments of the present disclosure and cannot be considered as limiting its scope.

FIG. 1 is a chart illustrating the length of outages after natural disasters, according to some example embodiments.

FIG. 2 is a map showing resource dependencies for operating a business center, according to some example embodiments.

FIG. 3 is a diagram containing charts showing probabilities of recovery times for different functions, according to some example embodiments.

FIG. 4 is a diagram illustrating a synthetic distribution network model pipeline, according to some example embodiments.

FIG. 5 is a diagram illustrating multiple steps involved during the recovery process, according to some example embodiments.

FIG. 6 is a flowchart of a model pipeline to generate recovery, according to some example embodiments.

FIG. 7 is a representation of the power distribution network, according to some example embodiments.

FIG. 8 is a diagram illustrating the impact on distribution and the restoration of power, according to some example embodiments.

FIG. 9 is a diagram illustrating some of the factors utilized in the power restoration simulation for the distribution network, according to some example embodiments.

FIG. 10 is a diagram illustrating a sample algorithm for calculating the importance of substations and nodes in the distribution network, according to some example embodiments.

FIG. 11 is a flowchart of a method for calculating the importance of the nodes in the distribution network, according to some example embodiments.

FIG. 12A is a flowchart of a second method for calculating the importance of the nodes, according to some example embodiments.

FIG. 12B is a flowchart of a third method for calculating the importance of the nodes, according to some example embodiments.

FIG. 13A is a graph illustrating a fragility function for a substation, according to some example embodiments.

FIG. 13B includes graphs illustrating some of the parameters used for calculating recovery time for substations in a flood, according to some example embodiments.

FIG. 14 includes graphs illustrating some of the parameters used for calculating recovery time for power poles in a flood, according to some example embodiments.

FIG. 15 is a table illustrating power recovery parameters for the 2014 Napa earthquake, according to some example embodiments.

FIG. 16 are charts showing some of the recovery parameters for earthquakes and wind events, according to some example embodiments.

FIG. 17 are charts illustrating the output of the Monte Carlo simulation, according to some example embodiments.

FIG. 18 are charts illustrating the availability of backup power in the recovery process, according to some example embodiments.

FIG. 19 is a flowchart of a method for estimating recovery of a distribution network after a disaster, according to some example embodiments.

FIG. 20 is a block diagram illustrating an example of a machine upon or by which one or more example process embodiments described herein may be implemented or controlled.

### DETAILED DESCRIPTION

Example methods, systems, and computer programs are directed to estimating recovery of a power distribution network after a disaster. Examples merely typify possible variations. Unless explicitly stated otherwise, components and functions are optional and may be combined or subdivided, and operations may vary in sequence or be combined or subdivided. In the following description, for purposes of explanation, numerous specific details are set forth to provide a thorough understanding of example embodiments. It will be evident to one skilled in the art, however, that the present subject matter may be practiced without these specific details.

One general aspect includes a method that includes an operation for generating a synthetic distribution network based on locations of substations in a geographical area. Further, the method includes operations for estimating damages to the synthetic distribution network based on disaster data, and for performing a simulation to estimate how the synthetic distribution network is repaired. The output of the simulation includes information on a recovery timeline for each building in the geographical area. Further, the method includes presenting, in a user interface, the recovery timeline for one or more buildings.

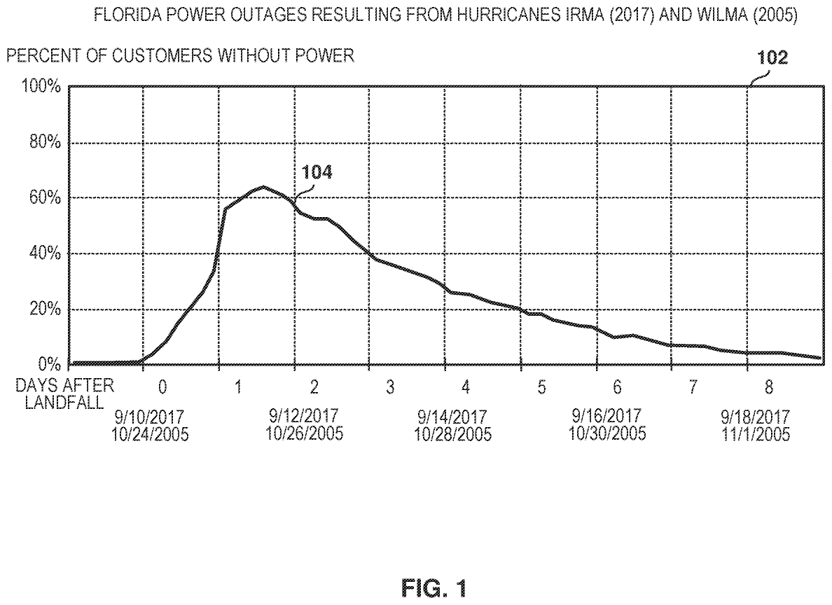

FIG. 1 is a chart 102 illustrating the duration of outages after natural disasters, according to some example embodiments. The illustrated example is for recovery of power after the hurricane Irma in 2017.

Line 104 shows the percentage of customers without power (vertical axis) as time progresses in days (horizontal axis) for hurricane Irma. At the peak, there were about 65% people without power and took about 9 days to get the power restored.

For Irma, recovering power cost $1.3 billion to Florida Power & Light (FPL), the local electricity company. Further, FPL used 6,000 employees and about 22,000 individuals outside of the company for the repairs.

FPL offered some facts regarding how the recovery took place. FPL's priorities for restoring power started with its own power plants, substations, and damaged transmission lines. Then, workers turned their attention to “critical facilities such as hospitals, police and fire stations, communication facilities, water treatment plants, and transportation providers.” Another driving factor is that FPL focused on “the largest number of customers in the shortest amount of time—including service to major thoroughfares that host supermarkets, pharmacies, gas stations and other needed community services.” This means that smaller groups of customers are a lower priority. Further, workers worked “around the clock until everyone has power again.” The company said that repairs and restoration would take a million-person hours to complete statewide.

The process to identify when power will be restored to a particular facility is complex and depends on how the utility companies schedule their jobs and prioritized according to need. The insights provided by FPL, as well as all other assumptions (e.g., availability of roads), can be used to model how the repair process takes place to estimate the time it takes to recover. Embodiments of the invention analyze multiple factors to model the power-restoration process in order to estimate the time it takes for power to be restored to a particular facility or building.

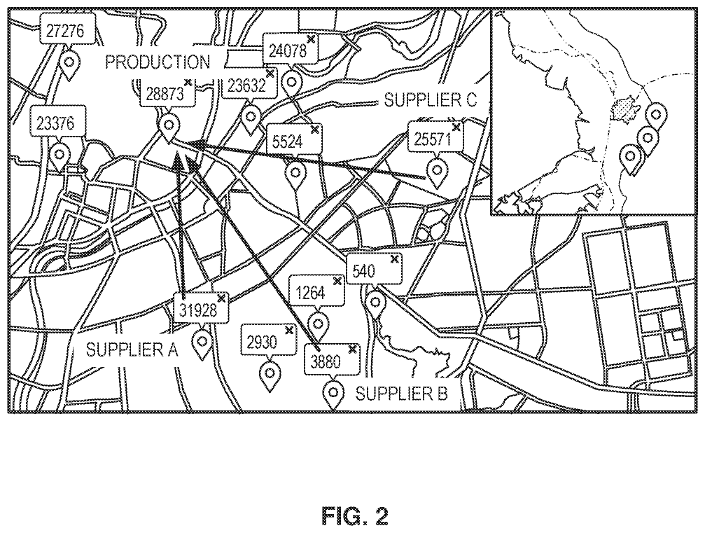

FIG. 2 is a map showing resource dependencies for operating a business center, according to some example embodiments. The map shows a plurality of business facilities (e.g., 27276, 23376, 28873, 23632) of different types (e.g., manufacturing plant, distribution plant, corporate offices, etc.), which may belong to the same company or to multiple companies. It is noted that a company may depend on other companies (e.g., material supplier) to be able to function, so identifying dependencies helps in estimating downtime of business operation.

In the illustrated example, a business facility 28873 depends on suppliers in facilities 25571, 31928, and 3880. This means that, in the case of power recovery, if business facility 28873 has power, but business facility 25571 does not have power, then business facility will not he able to be 100 percent functional.

For a business to be fully functional, multiple factors may have to be considered, beyond just having power. For example, if there is a flood, the building may suffer damage, so business recovery includes repairing the building (including damage components, such as electrical, flooring, etc.), getting power restored, etc.

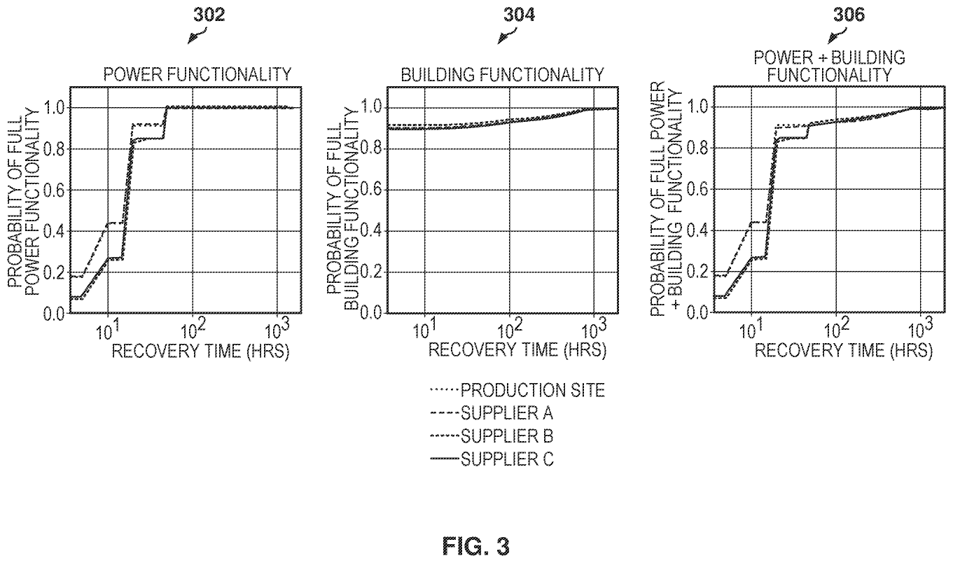

FIG. 3 contains charts showing probabilities of recovery times for different functions, according to some example embodiments. In some example embodiments, the modeling includes repairing the building and getting power restored, but other embodiments may include additional factors, such as transportation services being available for employees to come to the business facility.

Chart 302 shows the probability of full power functionality as a function of time (horizontal axis) in hours for a production site and three suppliers that impact the production side. Thus, for the production site, there is about 18% probability of full power at time 0 and gradually the probability improves to about 90% at about 20 hours, and full power at around 60 hours.

Chart 304 shows the probability of full building functionality as a function of time (horizontal axis) in hours for the production site and the three suppliers. It can he observed that the probability starts at around 90% and gradually increases to about 99% building functionality at around 700 hours.

When the information from charts 302 and 304 is combined, the result is chart 306 for the probability of full power in the building functionality over time. The combination shows that initially, power functionality is the main factor, but the tail end of the recovery may be delayed because of the time required for full building functionality.

It is noted that some embodiments are presented with reference to restoring electrical power, but the same principles may be used for other functions that are based on a distribution network, such as natural gas distribution, Internet fiber optic, telecommunication and cable distribution, road networks, drinking water distribution, etc.

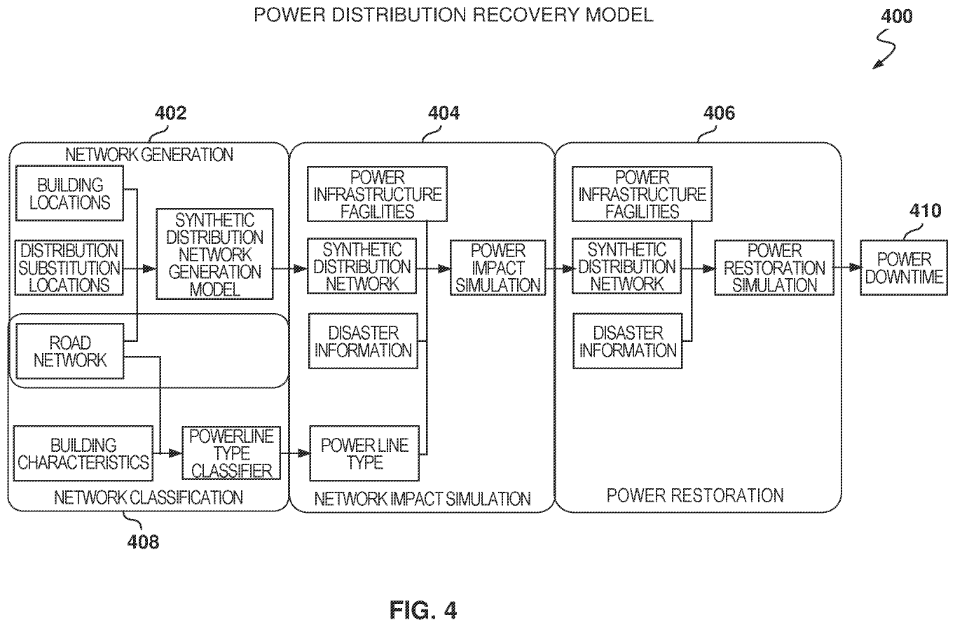

FIG. 4 illustrates a synthetic distribution network model 400, according to some example embodiments. The end goal is to estimate power downtime 410 for a business facility, a group of business facilities, a whole company, or some other facility with a physical presence that consumes power.

The model 400 includes several components to calculate the estimate of the power downtime 410. The model 400 includes a network generation model 402, a network classification model 408, a network impact simulation model 404, and a power restoration model 406.

The network generation model 402 models the generation and distribution of power, and it includes the locations of the buildings, the locations of the distribution substations, and the network of roads model, and these three components are used to generate the synthetic distribution network generation model. It is noted that substations refer to an intermediate distribution point for the utility, such as distribution points for power, network connectivity, roads, etc.

As used herein, a synthetic power distribution network is an artificially created power distribution network based on the known information about the real power distribution network. Typically, the actual distribution network is only known to the utility companies, and sometimes this information is incomplete even for the utility companies. In order to make the estimates, simulations are run with different types of possible distribution networks and the results aggregated to produce the synthetic distribution networks. By using this approach, it is possible to generate estimates for any location in the world, based on the publicly available data, e.g., building locations, substation locations, maps of roads.

The synthetic power distribution network is based on delivering power to distribution substations, and then distributing power from the substations to customers through transmission lines.

The network classification model 408 analyzes building characteristics and generates a classification of powerline types, based on the building characteristics and the network of roads.

The network impact simulation model 404 estimates the damage caused by the disaster (e.g., earthquake, flood, wind, hurricane, fire, cold wave, heat wave) based on several parameters. In some example embodiments, the parameters considered include fragility curves for power damage, a synthetic distribution network for power, disaster information, and type of power line.

Disaster information describes the intensity or severity of the disaster event. The information can be based on a live event (e.g., prediction of hurricane path and wind field), on a historical event (e.g., shake map of a past earthquake), from a hazard map (e.g., occurrence of a flood based on certain return period). The intensity of the event drives the impact analysis to help understand the damage to the power infrastructure.

The power restoration model 406 performs a power restoration simulation based on power recovery priorities, building-level power availability, and power recovery resources (e.g., people, utility tracks). The result of the power restoration simulation is the estimate for the power downtime 410. The power recovery priorities includes the rules to prioritize the work for restoring power, as discussed above, such as perform work that maximizes the number of users that will have power restored, repair substations first and then repair power lines, repair hospitals with higher priority than residences, etc.

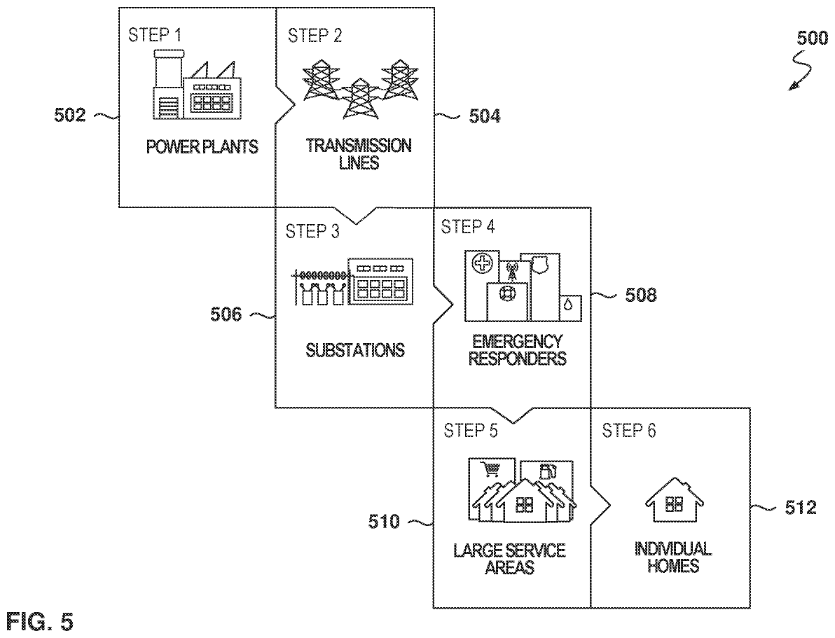

FIG. 5 illustrates a power-distribution recovery model 500, according to some example embodiments, which identifies the order of priorities when restoring, which then affects how to schedule resources to make repairs.

The first step 502 is to restore power plants, the primary source of power production, and includes assessing the damage to the power plants and repairing them.

The second step 504 is to restore the transmission lines, e.g., high-voltage transmission lines serving a large number of customers over a wide geographical area. In some example embodiments, the composition of the distribution network is unknown, and the synthetic distribution model is used to simulate the real distribution network. This means using the synthetic distribution network to estimate the damage to the network and then estimate how the damage to the synthetic distribution network is repaired.

The third step 506 is to repair the substations, and once the substations are repaired and brought online, the power may start flowing on the connected distribution lines.

The fourth step 508 is to repair emergency responders that are critical to the public health and safety, such as hospitals, medical offices, tire stations, police stations, water reclamation plants, and communication systems.

The fifth step 510 is to make repairs on large service areas. Crews are dispatched to prepare lines that will return service to the largest number of customers in the least amount of time, which includes repairing service lines 2 neighborhoods, industries, and businesses.

The sixth step 512 is to make repairs to individual homes and small groups of customers.

It is noted that the embodiments illustrated in FIG. 5 are examples and do not describe every possible embodiment. Other embodiments may utilize different priorities, additional criteria, fewer criteria, different order of criteria, etc. The embodiments illustrated in FIG. 5 should therefore not be interpreted to be exclusive or limiting, but rather illustrative.

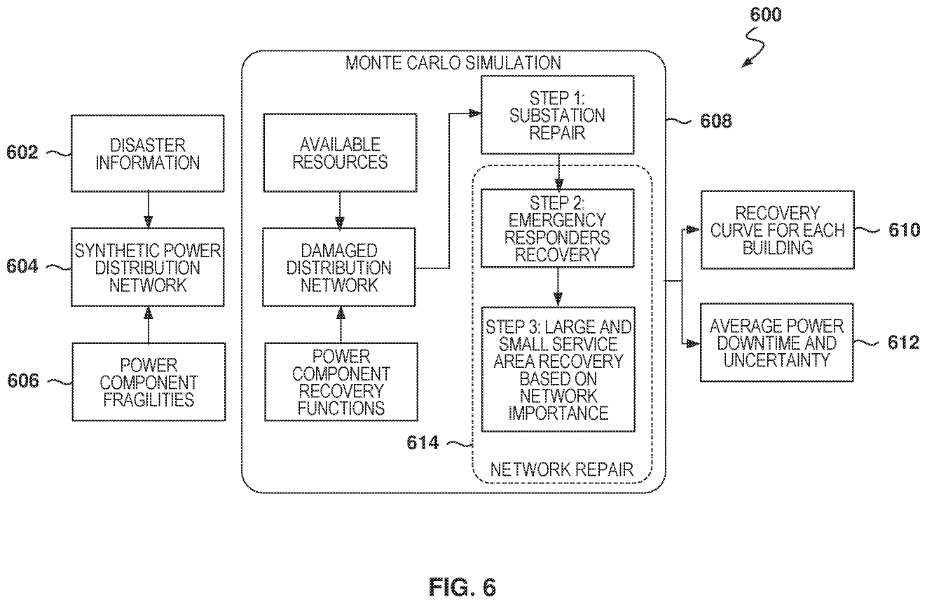

FIG. 6 is a flowchart for the power distribution recovery model 600, according to some example embodiments. The objective of the power distribution recovery model 600 is to use a priority-based power recovery model to estimate the power restoration process (expressed as a recovery curve 610 for each building) and the power downtime 612 for each customer, based on the damages calculated for the synthetic power distribution network 604.

The actual composition of the power-distribution network is not publicly available in most cases, and using the synthetic network enables generating an estimate of the building-level power recovery time, which is provided as probabilities with a defined uncertainty.

To obtain the outputs, a Monte Carlo simulation 608 is performed. Monte Carlo simulations are used to model the probability of different outcomes in a process that cannot easily be predicted due to the intervention of random variables. A Monte Carlo simulation performs analysis by building models of possible results by substituting a range of values—a probability distribution—for any factor that has inherent uncertainty. The simulation then calculates results many times, each time using a different set of random values from the probability functions. Depending upon the number of uncertainties and the ranges specified for them, a Monte Carlo simulation can utilize thousands or tens of thousands of recalculations before it is complete. The Monte Carlo simulation produces distributions of possible outcome values. In some example embodiments, 1,000 simulations are performed, but a different number of simulations may be performed, ranging from 200 to 20,000, although other values are also possible. More simulations will help with the convergence of the estimation.

The Monte Carlo simulation

often follows the following operations: 1) define a domain of possible inputs; 2) generate inputs randomly from a probability distribution over the domain; 3) perform a deterministic computation on the inputs; and 4) aggregate the results.

To perform the Monte Carlo simulation 608, information on the damaged distribution network, available resources for repairs, and recovery functions is used. The available resources include any type of constraint or input from the users regarding availability. The power component recovery functions are built to describe an estimate of how long it takes to repair each element of the power-distribution network.

Further, a priority-based model is used to represent what happens in real life when making repairs. For example, the priorities described in FIG. 5 may be used, but other types of priorities may also be used.

In the illustrated example of FIG. 6, the Monte Carlo simulation 608 includes two priorities: first, repair substations, and second, repair 614 the power-distribution network. To repair the power-distribution network, the recovery of emergency responders is prioritized first, followed by large and small service area recovery based on the importance of the elements in the power-distribution network.

For example, in simulation one, a given power line is simulated to be broken and a given substation down. In simulation two, the given substation is functional, but two other power lines are down, etc. Many simulations for many different scenarios are run, and in each of the simulations the calculation is made to repair everything.

The synthetic power distribution network 604 utilizes disaster information and power-network component fragility curves to estimate the damages to the power distribution network. The disaster information 602 describes the severity of the disaster, and the power component fragilities 606 describe how vulnerable each component in the distribution network is to the disaster. The disaster information 602 defines the severity of the disaster. For example, for a hurricane, it could be the trajectory and wind field of the hurricane. The disaster information 602 may be based on historical events, such as a shake map of an earthquake that happened in the past. The disaster information 602 may also be defined as a return period, such as in the case of the flood, where the return period gives the estimated time interval between events of a similar size or intensity.

The recovery curve 610 describes probabilistically estimates on when each building will have power again. Further, the average power downtime 612 is described as a recovery curve on how long the downtime is for each building.

Regarding the emergency responders recover, the important buildings include hospitals, police stations, fire stations, emergency facilities, water and sanitary authorities, nursing homes, and assisted-living facilities. Other embodiments may include additional facilities or fewer facilities.

The model to repair the emergency-responders facilities includes identifying the location of the important buildings, prioritizing the recovery sequence for the important buildings, and repairing the damages in the synthetic power distribution network for these buildings.

The recovery curve 610 for each building and the power downtime 612 for each customer, is useful for decision makers and business owners to develop mitigation plans by having a better understanding on the impact of disaster and the probability that there will be downtime because of the disaster.

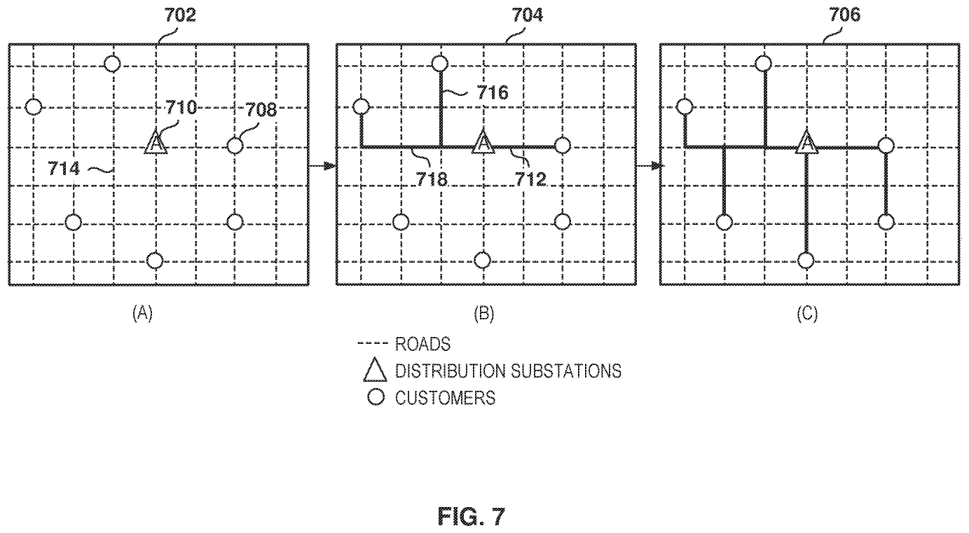

FIG. 7 is a representation of the power distribution network, according to some example embodiments. In some example embodiments, a synthetic power distribution network is created based on the locations of customers and substations.

Map 702 shows the locations of a substation 710 and a plurality of customers 708. A plurality of roads 714 are included in the map. In some example embodiments, it is assumed that the power lines run on the side of the roads 714, and the power lines for the synthetic power distribution network are added alongside the roads 714.

Paths to customers 708 are added one at a time, until all customers have a connection to the synthetic power distribution network. Map 704 shows how the synthetic power distribution network has added three paths 718, 712, and 716, to some customers from the substation 710. Further, additional paths are added to the rest of the customers, and the paths are typically added to the closest point in the already created paths. The resulting synthetic power distribution network is shown in map 706 where all customers 708 are connected to the substation 710.

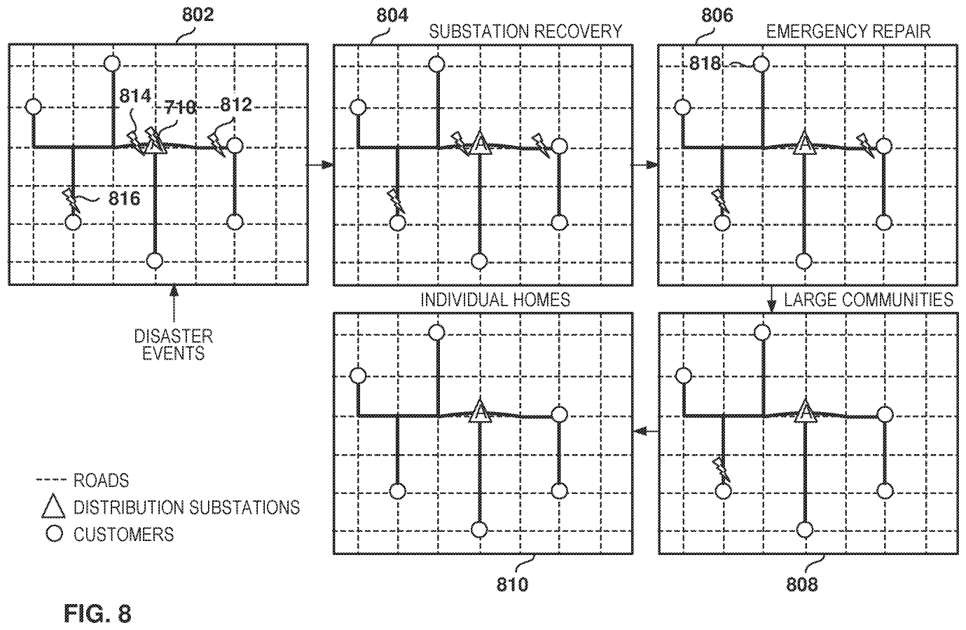

FIG. 8 illustrates the impact on distribution and the restoration of power, according to some example embodiments. Map 802 shows the damage to the synthetic power distribution network after a disaster. In this simulation, the substation 710 has been damaged, as well as power paths 812, 814, and 816.

The first priority is to fix the substation 710, and map 804 shows the situation after fixing the substation 710. Power paths 812, 814, and 816 still need repair.

In some example embodiments, the simulation model assumes that the repair crews will focus on repairing the power infrastructure or components that are necessary to bring power back to these facilities first. The next priority is to fix emergency buildings, such as building 818. Thus, the next operation is to fix broken power path 814. As a result, as shown in map 806, building 818 is now connected to the operating substation 710 so it has power.

In some example embodiments, the simulation model includes the following operations for repairing emergency buildings:
Predetermine the location of the emergency buildings;
Assign an importance value to the emergency buildings:
Rank the priority buildings based on the assigned importance;
Identify the damaged components and rank the damaged components based on the importance of the emergency buildings; and
Repair the damaged components based on the ranking to restore power for these buildings.

After the emergency buildings are repaired, the next priority is to fix large groups of homes, that is, maximize the number of homes that will recuperate power for each repair. In the illustrated example, power is restored to a large community when power path 812 is repaired. Map 808 shows the result of fixing the power path 812.

Finally, paths to individual homes are fixed, such as power path 816. Map 810 shows the synthetic power supply network after all repairs are made.

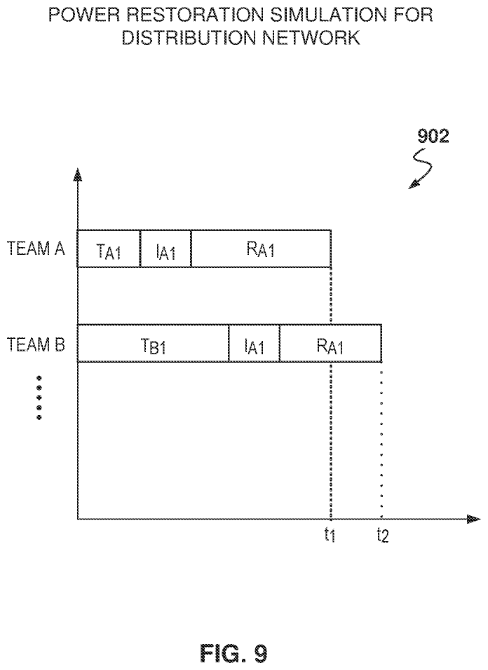

FIG. 9 illustrates some of the factors utilized in the power restoration simulation for the distribution network, according to some example embodiments.

In a damaged distribution system, for some example embodiments, the substation has the first priority to be repaired. Under extreme disaster events, some substations might be shut down to prevent damage to the power grid. Therefore, there is an expectation that the substation has a relatively high probability of being damaged (e.g., more than 50%, but other values are also possible).

The substation repair time, different for each distribution substation, consists of three components: the transmission downtime Tₜᵣₐₙₛ, the inspection time Tᵢ, and the repair time Tᵣ. Thus, the time to repair the substation T_{sub} is calculated as follows:

T_{sub}=Tₜᵣₐₙₛ+Tᵢ+Tᵣ

The first component to consider is the power delivery through the transmission system. Typically, the transmission system to substations is built with reliability protocols and should recover very fast. Tₜᵣₐₙₛ is the time it takes for the transmission system to be repaired before power can be delivered to the distribution substation.

The second time factor considered is the inspection time Tᵢ of the substation, which is the time required to inspect the damage situation of the substation to evaluate that the substation can be turned back online for operation. In some example embodiments, it is assumed that all the inspections start at the same time in parallel for all substations. After the inspection, if there is no damage to the substation, then the substation will be back in operation, and customers within the substation's service area will get power back if they do not have any damage in their distribution network.

If there is a damage in the substation, there will be an extra repair time Tᵣ for the substation. In some example embodiments, Tr is estimated based on crew availability, inventory stock of repair parts, and damage severity of the equipment.

After the substations are repaired, in some example embodiments, it is assumed that each substation's service area is independent, and the number of crew teams are assigned given the damage situation. The available crews (e.g., A, B, C, . . . ) for repairs are then scheduled to repair the network. Each crew team is assigned the next highest priority job within a certain distance of their location.

Each crew is assigned a repair, identified by a repair identifier, such as an integer number. Further, T_{Xn}, is the travel time for crew X to the damaged site n from the original location of crew X (substation, or utility site).

T_{Xn}, is a function of the following factors:
Distance d between the current location and repair site;
Road damage r on the route to the repair site;
Inspection time I to assess the damage.
Repair time R. Further, R is a function of: distance dr to inventory repository; road damage rr on the route to the inventory repository; boolean flag IA indicating if inventory for repairs is available; and type of repair work RW.

Chart 902 shows the repair times of the different crews over time. For example, repair time for crew A for repair 1 is t₁=T_{A1}+I_{A1}+R_{A1}, repair time for crew B for repair 2 is t₂=T_{B2}+I_{B2}+R_{B2}.

After each component is repaired, (e.g., at t₁), the connectivity of the network is reevaluated to determine which nodes now have access to the substation. That is, at t₁, a set of buildings referred to as {t₁} now have access to power. The power recovery time for these buildings {t₁} will be T_{sub}+t₁. After the repair is done, the team is assigned the job with the highest priority within the region where the crew operates.

Further, T_{comp}(b) is the time to repair the damaged components that are used to connect the building b to the distribution grid. The DTₜ(b) for the building b to get power back is defined as:

DTₜ(b)=T_{sub}(b)+T_{comp}(b)

Here, T_{sub}(b) is the time to repair the substation, or substations, required to provide power to building b.

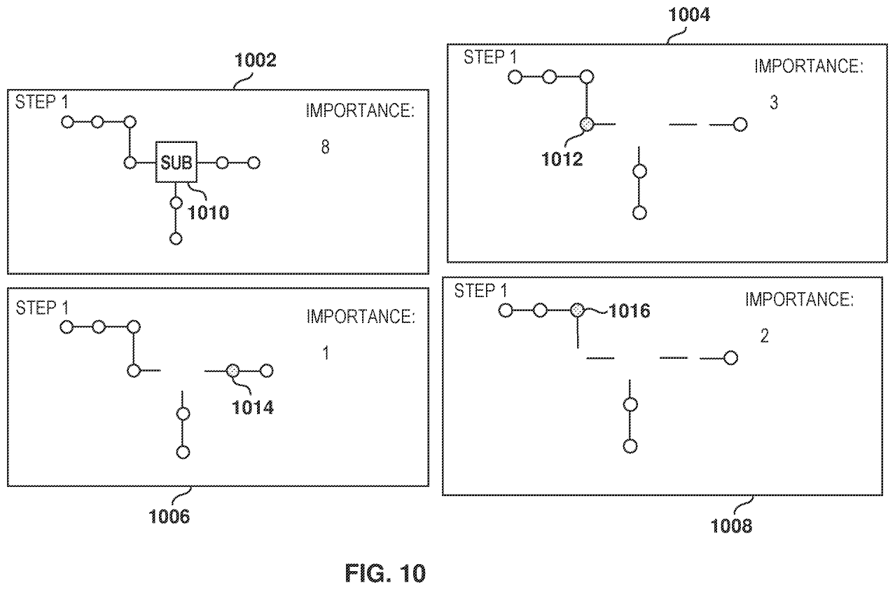

FIG. 10 illustrates a sample algorithm for calculating the importance of substations and nodes in the distribution network, according to some example embodiments. As discussed above, the importance is used for prioritizing the work in order to restore power to buildings with higher importance first. By prioritizing repairs, service to areas with more customers will be repaired before repairing service to rural or isolated areas, that is, maximizing the utility of the repair work overtime.

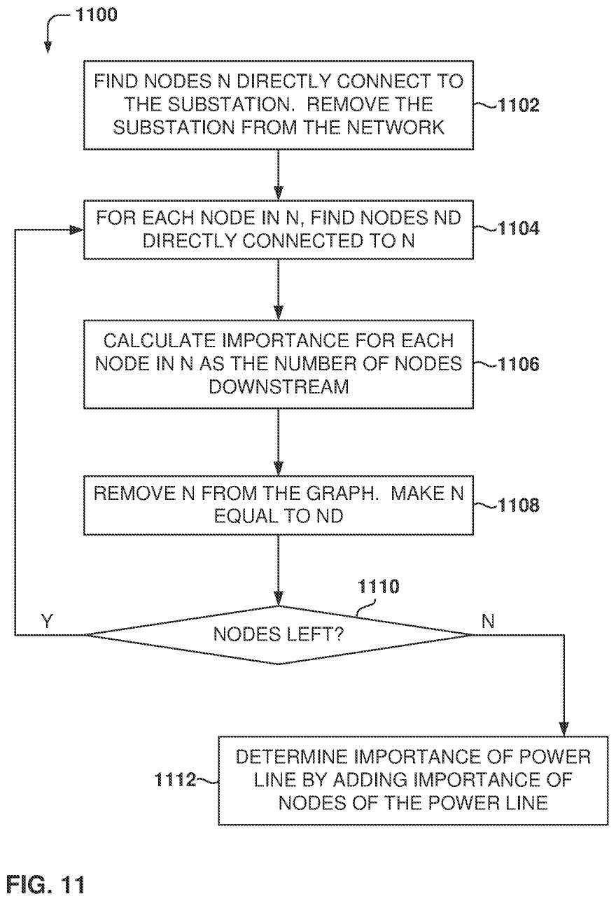

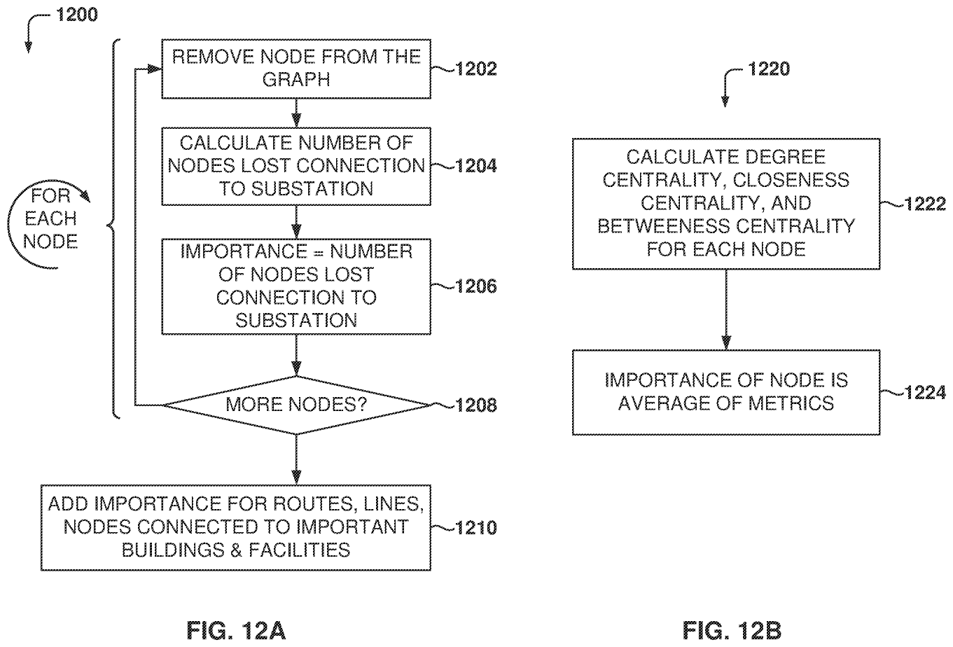

Chart 1002 illustrates a substation 1010 with eight nodes, where each node is a distribution component in the network, such as a power pole, a transmission line, or an end customer. More details about methods for calculating the importance is provided below with reference to FIGS. 11 and 12A-12B. The method illustrated in FIG. 10 corresponds to the method described with reference to FIG. 11.

To calculate the importance of the substation, the method counts the number of nodes that lose power if the substation goes down. This count is then used for the importance of the substation. In this case, substation 1010 has an importance of eight, because if the substation 1010 goes down, 10 nodes lose power.

Afterwards, the substation is removed from the map and the method proceeds to calculate the importance of the nodes connected to the substation 1010. Chart 1004 shows the importance of node 1012. If node 1012 goes down, three nodes will lose connectivity, therefore, the importance of node 1012 is three. Similarly, chart 1006 shows that the importance of node 1014 is one because there is one node downstream from the node 1014.

After the importance of the nodes connected to the substation 1010 is calculated, the nodes are removed, and the method continues to calculate the importance of the nodes next in the hierarchy as it relates to proximity to the substation 1010. Thus, chart 1008 shows that the importance of node 1016 is to because there are two other nodes downstream from node 1016. The method continues until the importance of all the nodes is calculated.

By using the importance of value calculated for all the nodes, the model guarantees that larger service areas are recovered first, followed by individual homes or rural areas.

FIG. 11 is a flowchart of a method 1100 for calculating the importance of the nodes in the distribution network, according to some example embodiments. This method is referred used for a pure radial network without redundant paths.

At operation 1102, the method 1100 identifies the nodes N directly connected to the substation, and the substation is removed from the network.

From operation 1102, the method 1100 flows to operation 1104 where the nodes ND directly connected to each node in N are identified.

From operation 1104, the method 1100 flows to operation 1106 where the importance for each node in N is the number of nodes downstream of the node, where the downstream nodes of a given node are those nodes that receive power through the given node. That is, if the given node is damaged, the downstream nodes will not receive any power.

From operation 1106, the method 1100 flows to operation 1108, where the nodes in N are removed from the graph. The nodes in ND are then assigned to N.

At operation 1110, a check is made to determine if there are nodes left in the graph (e.g., N is not empty). If there are nodes left, the method flows back to operation 1104, and if there are no nodes left, the method flows to operation 1112.

At operation 1112, the importance of each power line is calculated by adding up the importance of the nodes in the power line.

FIG. 12A is a flowchart of a second method 1200 for calculating the importance of the nodes, according to some example embodiments.

Operations 1202, 1204, and 1206 are performed for each node in the graph, one node at a time. At operation 1202, the node is removed from the graph, and at operation 1204, the number of nodes that lose connection to the substation is calculated. At operation 1206, the importance of the node is equal to the number of nodes that lost connection to the substation when the node is removed.

At operation 1208, a check is made to determine if there are more nodes for calculating the importance. Once the importance for all the nodes is calculated, the method 1200 flows to operation 1210, where the emergency buildings (e.g., important buildings) are assigned a higher priority.

FIG. 12B is a flowchart of a third method 1220 for calculating the importance of the nodes, according to some example embodiments. At operation 1222, the method 1220 calculates the degree centrality, closeness centrality, and betweenness centrality for each node. Degree centrality assumes that the greater the number of adjacent nodes, the greater their influence. Further, closeness centrality is represented by the reciprocal of the distance between the given node and other nodes in the network and is a measurement of how long it takes information to spread from a given node to another. Betweenness centrality measures node importance by means of the ratio of the shortest path over the nodes to the number of all paths.

At operation 1224, the importance of each node is based on the calculated degree centrality, closeness centrality, and betweenness centrality. In some example embodiments, the importance is equal to the average of these metrics, but other embodiments may utilize other equations for combining these parameters.

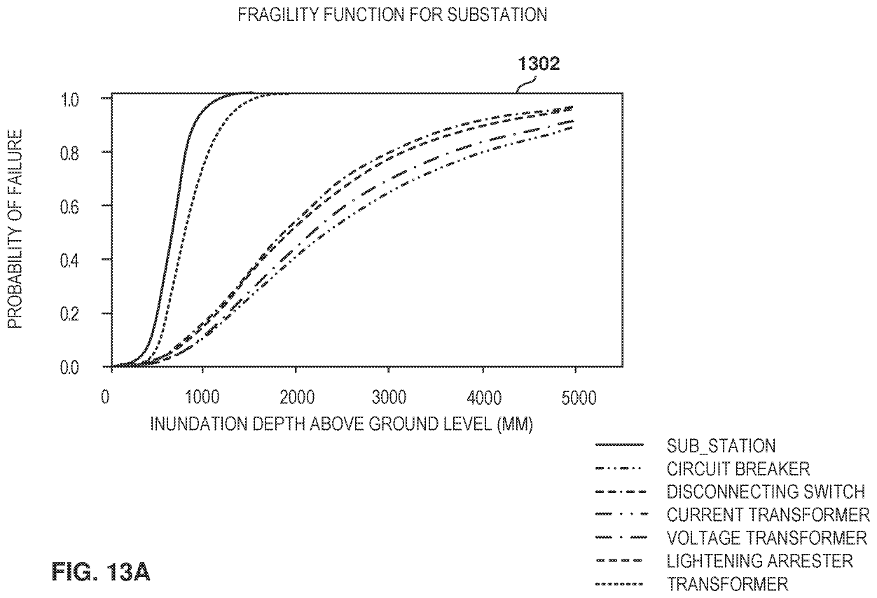

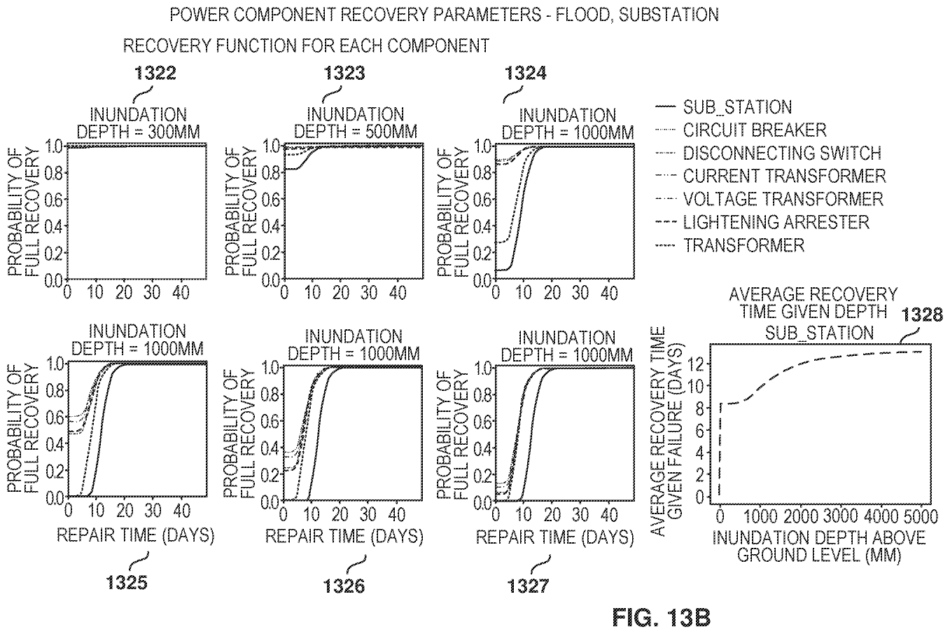

FIG. 13A illustrates a fragility function 1302 for a substation, according to some example embodiments. A fragility function is a mathematical function that expresses the probability that some undesirable event occurs (e.g., that an asset—a facility or a component—reaches or exceeds some clearly defined limit state) as a function of some measure of environmental excitation (e.g., a measure of acceleration, deformation, or force in an earthquake, a flood level, a hurricane strength).

The chart of fragility function 1302 shows fragility function for the substation overall and for a plurality of components of the substation, including circuit breaker, disconnecting suites, current transformer, voltage transformer, lightning arrester, and transformer.

Each line provides the probability of failure according to the depth above ground for the flooding event. These fragility curves, with the corresponding probabilities of failure, are the inputs for the simulation to calculate probabilities of recovery times.

In some example embodiments, the fragility curves are calculated based on historical data from past flooding events.

FIG. 13B illustrates some of the parameters used for calculating recovery time for substations in a flood, according to some example embodiments. The recovery function charts 1322-1327 show the probability of full recovery (vertical axis) for a given inundation depth (e.g., 300 mm for chart 1322, 500 mm for chart 1323, etc.) along the repair times (horizontal axis).

In some example embodiments, for the substation recovery development, it is assumed that the repair time of all substation components conditioned on component failure, follow a log-normal distribution with median equal to 8 days and dispersion (standard deviation of log of repair time) equal to 0.3, but other values may also be used. Based on this assumption, the following recovery function charts 1322-1323 are calculated for the different depths.

As the recovery function charts 1322-1323 show, the repair times increase as the inundation level increases, as expected. The recovery time is negligible with inundation depth equal to 300 mm because of low probability of failure at this level. As the inundation depth increases, the probability of component failure increases, and the repair time to achieve 100% recovery increases.

Based on the recovery function charts 1322-1323, the average recovery time based on depth 1328 is calculated for the substation. The recovery function shows the average recovery time in days (vertical axis) based on the inundation depth (horizontal axis). The chart 1302 shows that once there is any flooding, the recovery time may be over 8 days if the substation has failed, however, the chances of substation failure at small inundation depths are relatively insignificant as seen in chart 1302. As the depth level increases, the recovery time also increases (e.g., 12 days for 2000 mm depth).

In some example embodiments, historical data is used to obtain the recovery functions for each component. By aggregating this information, the recovery time is calculated, and this value is used as input for the simulations to describe how long it takes for a substation to recover during flooding.

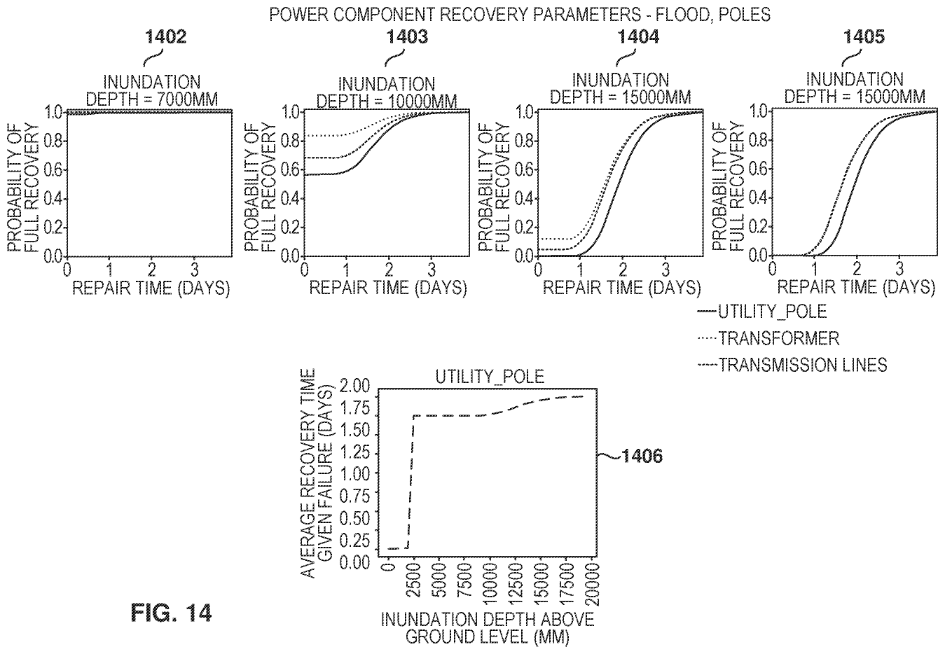

FIG. 14 illustrates some of the parameters used for calculating recovery time for power poles in a flood, according to some example embodiments. The recovery functions 1402-1405 for the poles in a flood situation show the probability of recovery (vertical axis) for a given inundation depth (e.g., 300 mm for chart 1322, 500 mm for chart 1323, etc.) along the repair times (horizontal axis). Three lines are included for the utility pole, the transformer, and the transmission lines.

Comparing the recovery function charts 1402-1405 for the poles to the recovery function charts 1322-1323 for the substation in FIG. 13B, it is observed that the probabilities of failure are lower, which makes sense since poles tend not to fail unless there is a flood with high water depth.

Based on the recovery function charts 1402-1405, the average recovery time based on depth chart 1406 is calculated for the utility pole. The recovery function shows the average recovery time in days (vertical axis) based on the inundation depth (horizontal axis). The chart shows that there is no damage to the pole until a certain depth (e.g., two meters) and the recovery time then varies between 1.75 and two days. In some example embodiments, using historical data is used to obtain the recovery functions for the poles.

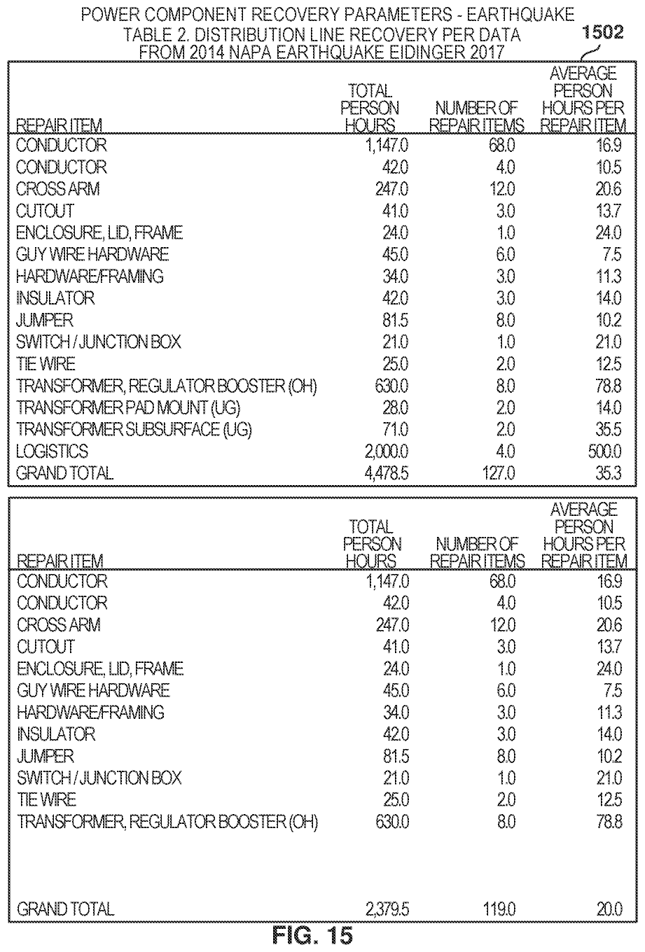

FIG. 15 is a table illustrating power recovery parameters for the 2014 Napa earthquake, according to some example embodiments. Fragility functions may also be used to analyze earthquake damage and recovery probabilities. The fragility functions may be calculated for different elements, such as disconnect switches, lightning arrestors, circuit switches, transformers, etc.

The data from past earthquakes is utilized to determine the fragility functions. Similarly, the fragility functions for the substations may be calculated for earthquakes. Further, the fragility functions from the different components, and the historical data is used to calculate the damage and recovery of substations under earthquake scenarios.

From the data observed in the 2014 Napa earthquake (2017), average recovery time for overhead lines can be estimated as 20 person hours, as illustrated in table 1502. The time to recover underground transmission lines is typically 3-4 times more than overhead transmission lines. Hence, the average time to recover underground transmission lines is estimated to be 70 person hours. Though the duration of shifts and number of shifts per day can vary from situation to situation, an assumption of 3.8-hour shifts is used for substation repair teams per day. Based on this, the average recovery time for overhead lines and underground lines can he estimated to be between 0.8 and 3 person-days, respectively.

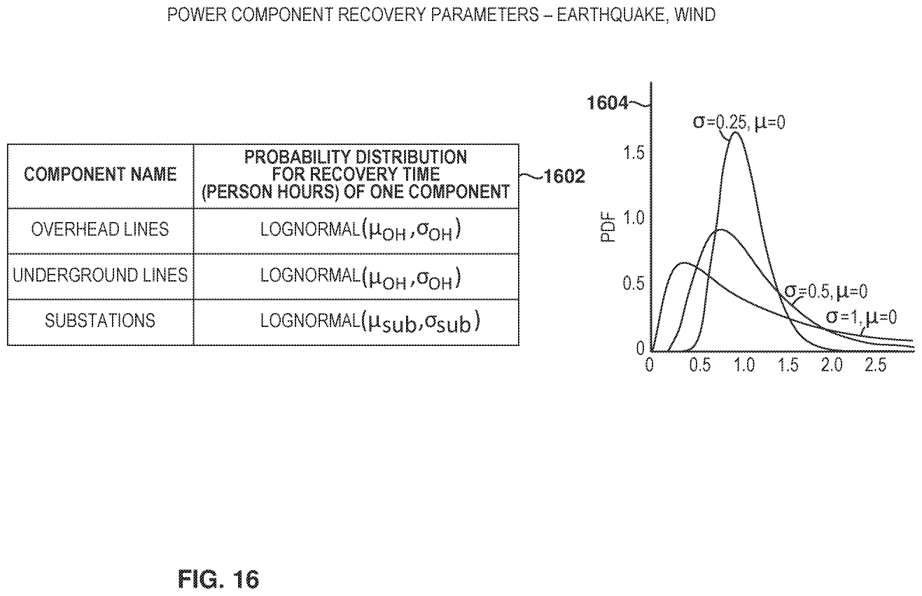

FIG. 16 shows some of the recovery parameters for earthquakes and wind events, according to some example embodiments. In some example embodiments, the probability distribution for recovery times is approximated for each of the components, such as overhead lines, underground lines, and substations.

As illustrated in table 1602, each component is represented by a lognormal function with a certain average in standard deviation. The chart 1604 illustrates the lognormal distributions for the overhead lines, underground lines, and substations. The horizontal axis is for the recovery time in person-hours, and the vertical axis is for the probability of the component being recovered.

As seen in chart 1604, the substations have a longer recover time than the underground lines and overhead lines. The lognormal distributions are calculated based on analysis of historical data for flood events. These lognormal distributions are then used to sample values during the Monte Carlo simulations.

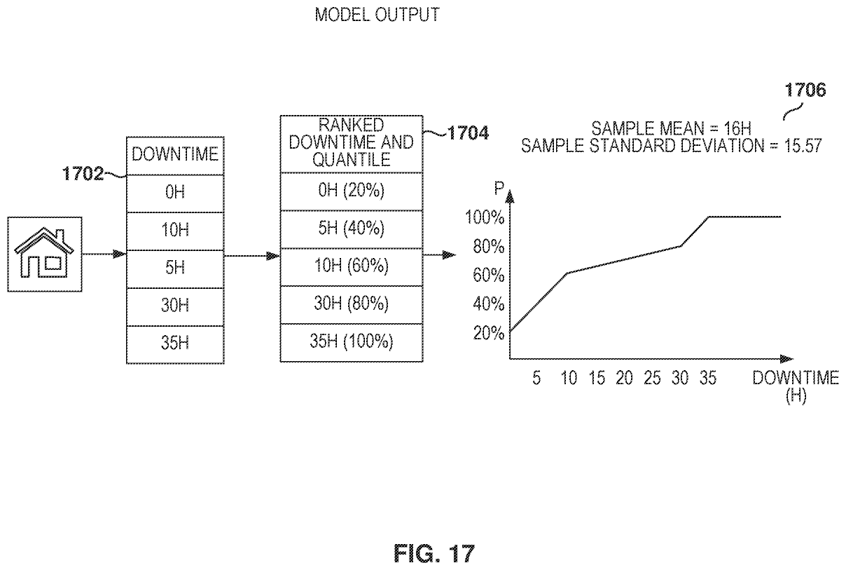

FIG. 17 illustrates the output of the Monte Carlo simulation, according to some example embodiments. The output of the Monte Carlo simulation is the power downtime for each building. In some example embodiments, a large number of trials are run (e.g., 1000) to achieve convergence for the estimated random variable.

In some embodiments, the downtime values 1702 are ranked and binned according to quantile, as shown in table 1704, with quantile bins for 20%, 40%, 60%, 80%, and 100%, but other bin sizes may be utilized.

The recovery curve 1706 is created based on the power downtime samples for each building. The curve is defined as the probability (vertical axis) of having power recovered at a given time (horizontal axis). This probability is expressed as P(power on |T<t). This is also referred to as the empirical distribution function.

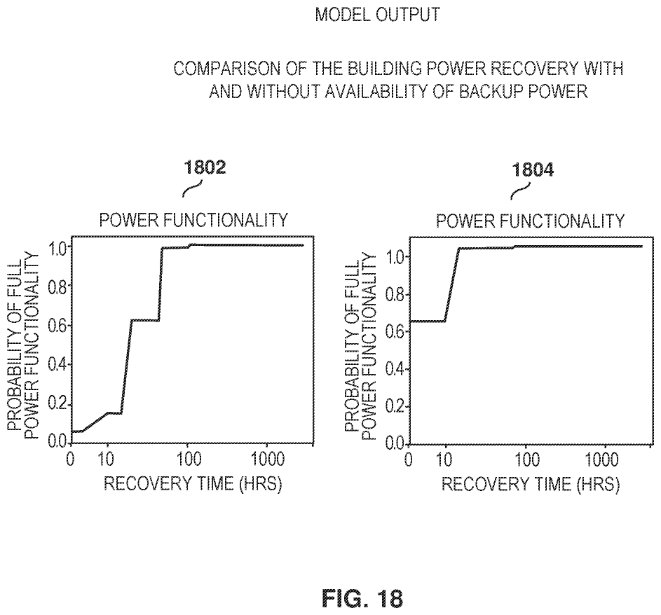

FIG. 18 illustrates the availability of backup power in the recovery process, according to some example embodiments. Some buildings have emergency backup power provided, such as solar, backup fuel generator, and backup batteries. The availability of power may also be simulated when backup power is available. FIG. 18 illustrates a comparison of the recovery for a building with and without backup power.

As an example, chart 1802 illustrates the recovery time without backup power, and chart 1804 shows the availability with backup power of 3 days. In order to model the power downtime reduction due to availability of power backup, the power recovery curve is shifted towards left along the x-axis by distance equal to the duration of power backup. It reflects that with a power backup of d days (d=3 days in the chart 1804), the probability of power on at time in an impacted building is equal to the probability of power on in a building at t+d in a building without any power backup.

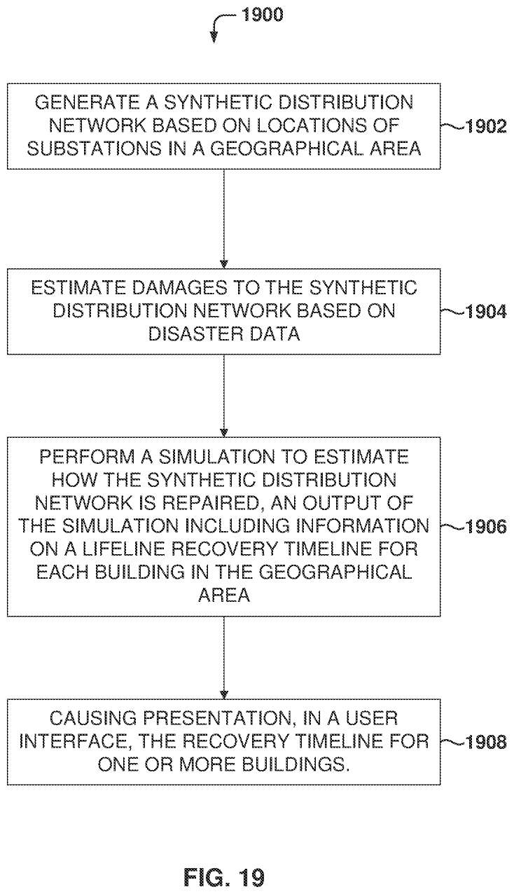

FIG. 19 is a flowchart of a method 1900 for estimating recovery of a distribution network after a disaster, according to some example embodiments. While the various operations in this flowchart are presented and described sequentially, one of ordinary skill will appreciate that some or all of the operations may be executed in a different order, be combined or omitted, or be executed in parallel.

Operation 1902 is for generating a synthetic distribution network based on locations of substations in a geographical area.

From operation 1902, the method 1900 flows to operation 1904 for estimating damages to the synthetic distribution network based on disaster data

From operation 1904, the method 1900 flows to operation 1906 for performing a simulation to estimate how the synthetic distribution network is repaired. The output of the simulation includes information on a recover timeline for each building in the geographical area.

From operation 1906, the method 1900 flows to operation 1908 for causing presentation, in a user interface, the recovery timeline for one or more buildings.

In one example, the synthetic distribution network is an artificially created distribution network based on known information about a real distribution network.

Estimating the damages to the synthetic distribution network may be based on fragility curves for the substations and distribution lines in the geographical area.

Further, performing the simulation further includes estimating an order of repairs to the synthetic distribution network based on priorities for restoring supply to the buildings.

In one aspect, the order of repairs includes: 1) repairing substations; 2) repairing distribution to emergency buildings; and 3) repairing distribution lines based on a number of customers affected by each distribution line.

Estimating the order of repairs may include determining an importance for each component of the synthetic distribution network, the importance indicating how many buildings receive supply via the corresponding element of the synthetic distribution network.

In one example, performing the simulation further includes estimating a time of repair for one substation by adding transmission downtime, inspection time, and repair time for the substation.

In another example, performing the simulation further includes estimating a time of repair for one substation by adding travel time to the distribution line, inspection time of the power line; and repair time for the distribution line.

Performing the simulation further includes assigning damage to substations and distribution lines based on corresponding fragility functions.

The disaster data may include a water inundation level in the building caused by a flood.

Further, the disaster data may include an amount of shaking of the building caused by an earthquake.

Another general aspect is for a system that includes a memory comprising instructions and one or more computer processors. The instructions, when executed by the one or more computer processors, cause the one or more computer processors to perform operations comprising: generating a synthetic distribution network based on locations of substations in a geographical area; estimating damages to the synthetic distribution network based on disaster data; performing a simulation to estimate how the synthetic distribution network is repaired, an output of the simulation including information on a recovery timeline for each building in the geographical area; and presenting, in a user interface, the recovery timeline for one or more buildings.

In yet another general aspect, a machine-readable storage medium (e.g., a non-transitory storage medium) includes instructions that, when executed by a machine, cause the machine to perform operations comprising: generating a synthetic distribution network based on locations of substations in a geographical area; estimating damages to the synthetic distribution network based on disaster data; performing a simulation to estimate how the synthetic distribution network is repaired, an output of the simulation including information on a recovery timeline for each building in the geographical area; and presenting, in a user interface, the recovery timeline for one or more buildings.

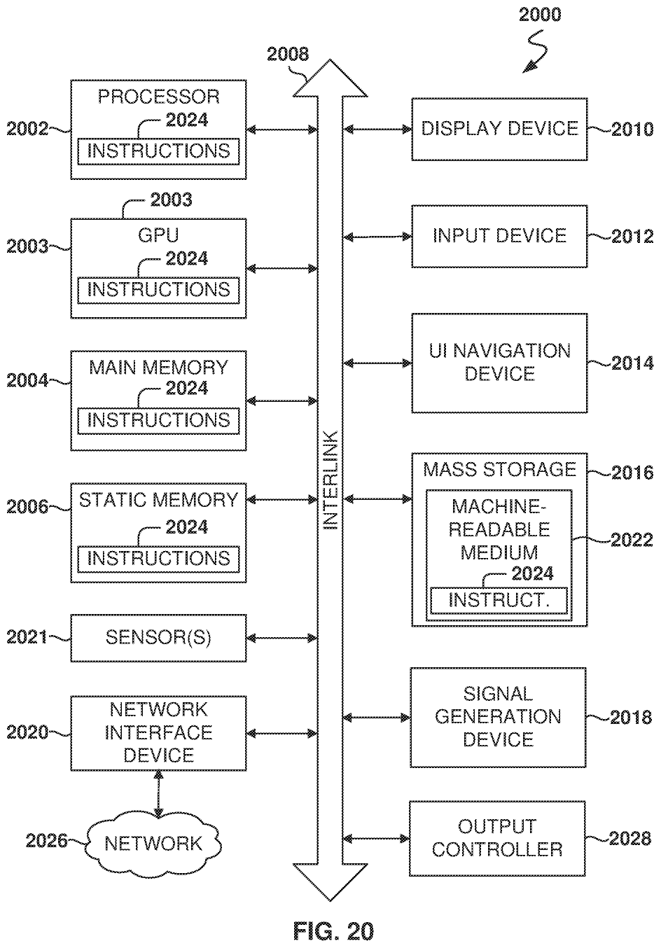

FIG. 20 is a block diagram illustrating an example of a machine 2000 upon or by which one or more example process embodiments described herein may be implemented or controlled. In alternative embodiments, the machine 2000 may operate as a standalone device or may be connected (e.g., networked) to other machines. In a networked deployment, the machine 2000 may operate in the capacity of a server machine, a client machine, or both in server-client network environments. In an example, the machine 2000 may act as a peer machine in a peer-to-peer (P2P) (or other distributed) network environment. Further, while only a single machine 2000 is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, a number of components, or mechanisms. Circuitry is a collection of circuits implemented in tangible entities that include hardware (e.g., simple circuits, gates, logic). Circuitry membership may be flexible over time and underlying hardware variability. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits) including a computer-readable medium physically modified (e.g., magnetically, electrically, by moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 2000 may include a hardware processor 2002 (e.g., a central processing unit (CPU), a hardware processor core, or any combination thereof), a graphics processing unit (GPU) 2003, a main memory 2004, and a static memory 2006, some or all of which may communicate with each other via an interlink (e.g., bus) 2008. The machine 2000 may further include a display device 2010, an alphanumeric input device 2012 (e.g., a keyboard), and a user interface (UI) navigation device 2014 (e.g., a mouse). In an example, the display device 2010, alphanumeric input device 2012, and UI navigation device 2014 may be a touch screen display. The machine 2000 may additionally include a mass storage device (e.g., drive unit) 2016, a signal generation device 2018 (e.g., a speaker), a network interface device 2020, and one or more sensors 2021, such as a Global Positioning System (GPS) sensor, compass, accelerometer, or another sensor. The machine 2000 may include an output controller 2028, such as a serial (e.g., universal serial bus (USB)), parallel, or other wired or wireless (e.g., infrared (IR), near field communication (NFC)) connection to communicate with or control one or more peripheral devices (e.g., a printer, card reader).

The mass storage device 2016 may include a machine-readable medium 2022 on which is stored one or more sets of data structures or instructions 2024 (e.g., software) embodying or utilized by any one or more of the techniques or functions described herein. The instructions 2024 may also reside, completely or at least partially, within the main memory 2004, within the static memory 2006, within the hardware processor 2002, or within the GPU 2003 during execution thereof by the machine 2000. In an example, one or any combination of the hardware processor 2002, the GPU 2003, the main memory 2004, the static memory 2006, or the mass storage device 2016 may constitute machine-readable media.

While the machine-readable medium 2022 is illustrated as a single medium, the term “machine-readable medium” may include a single medium, or multiple media, (e.g., a centralized or distributed database, and/or associated caches and servers) configured to store the one or more instructions 2024.

The term “machine-readable medium” may include any medium that is capable of storing, encoding, or carrying instructions 2024 for execution by the machine 2000 and that cause the machine 2000 to perform any one or more of the techniques of the present disclosure, or that is capable of storing, encoding, or carrying data structures used by or associated with such instructions 2024. Non-limiting machine-readable medium examples may include solid-state memories, and optical and magnetic media. In an example, a massed machine-readable medium comprises a machine-readable medium 2022 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 2024 may further be transmitted or received over a communications network 2026 using a transmission medium via the network interface device 2020.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications. additions, and improvements fall within a scope of embodiments of the present disclosure as represented by the appended claims. The specification and drawings are, accordingly, to be regarded in an illustrative rather than a restrictive sense.

What is claimed is:

1. A computer-implemented method comprising:
generating, by one or more hardware processors, a synthetic distribution network based on locations of substations in a geographical area;
estimating, by the one or more hardware processors, damages to the synthetic distribution network based on disaster data;
performing a simulation to estimate how the synthetic distribution network is repaired, an output of the simulation including information on a lifeline recovery timeline for each building in the geographical area; and
causing presentation, in a user interface, the recovery timeline for one or more buildings.

2. The computer-implemented method as recited in claim 1, wherein the synthetic distribution network is an artificially created distribution network based on known information about a real distribution network.

3. The computer-implemented method as recited in claim 1, wherein estimating the damages to the synthetic distribution network is based on fragility curves for the substations and distribution lines in the geographical area.

4. The computer-implemented method as recited in claim 1, wherein performing the simulation further includes:
estimating an order of repairs to the synthetic distribution network based on priorities for restoring supply to the buildings.

5. The computer-implemented method as recited in claim 4, wherein the order of repairs includes:
1) repairing substations;
2) repairing distribution to emergency buildings; and
3) repairing distribution lines based on a number of customers affected by each distribution line.

6. The computer-implemented method as recited in claim 4, wherein estimating the order of repairs includes:
determining an importance for each component of the synthetic distribution network, the importance indicating how many buildings receive supply via the corresponding element of the synthetic distribution network.

7. The computer-implemented method as recited in claim 1, wherein performing the simulation further includes:
estimating a time of repair for one substation by adding transmission downtime, inspection time, and repair time for the substation.

8. The computer-implemented method as recited in claim 1, wherein performing the simulation further includes:
estimating a time of repair for one distribution line by adding travel time to the distribution line, inspection time of the distribution line;
and repair time for the distribution line.

9. The computer-implemented method as recited in claim 1, wherein performing the simulation further includes:
assigning damage to substations and distribution lines based on corresponding fragility functions.

10. The computer-implemented method as recited in claim 1, wherein the disaster data includes a water inundation level in the building caused by a flood.

11. The computer-implemented method as recited in claim 1, wherein the disaster data includes an amount of shaking of the building caused by an earthquake.

12. A system comprising:
a memory comprising instructions; and
one or more computer processors, wherein the instructions, when executed by the one or more computer processors, cause the system to perform operations comprising:
generating a synthetic distribution network based on locations of substations in a geographical area;
estimating damages to the synthetic distribution network based on disaster data;
performing a simulation to estimate how the synthetic distribution network is repaired, an output of the simulation including information on a recovery timeline for each building in the geographical area; and
causing presentation, in a user interface, the recovery timeline for one or more buildings.

13. The system as recited in claim 12, wherein the synthetic distribution network is an artificially created distribution network based on known information about a real distribution network.

14. The system as recited in claim 12, wherein estimating the damages to the synthetic distribution network is based on fragility curves for the substations and distribution lines in the geographical area.

15. The system as recited in claim 12, wherein performing the simulation further includes:
estimating an order of repairs to the synthetic distribution network based on priorities for restoring supply to the buildings.

16. A tangible machine-readable storage medium including instructions that, when executed by a machine, cause the machine to perform operations comprising:
generating a synthetic distribution network based on locations of substations in a geographical area;
estimating damages to the synthetic distribution network based on disaster data;
performing a simulation to estimate how the synthetic distribution network is repaired, an output of the simulation including information on a recovery timeline for each building in the geographical area; and
causing presentation, in a user interface, the recovery timeline for one or more buildings.

17. The tangible machine-readable storage medium as recited in claim 16, wherein the synthetic distribution network is an artificially created distribution network based on known information about a real distribution network.

18. The tangible machine-readable storage medium as recited in claim 16, wherein estimating the damages to the synthetic distribution network is based on fragility curves for the substations and distribution lines in the geographical area.

19. The tangible machine-readable storage medium as recited in claim 16, wherein performing the simulation further includes:
estimating an order of repairs to the synthetic distribution network based on priorities for restoring supply to the buildings.

20. The tangible machine-readable storage medium as recited in claim 19, wherein the order of repairs includes:
1) repairing substations;
2) repairing distribution to emergency buildings; and
3) repairing distribution lines based on a number of customers affected by each distribution line.
